(19) United States
(12) Patent Application Publication
(10) Pub. No.: US 2024/0282762 A1
(43) Pub. Date: Aug. 22, 2024

(54) SEMICONDUCTOR DEVICE AND METHOD OF MANUFACTURING SEMICONDUCTOR DEVICE

(71) Applicant: ROHM CO., LTD., Kyoto (JP)

(72) Inventor: Shota IZUMI, Kyoto (JP)

(73) Assignee: ROHM CO., LTD., Kyoto (JP)

(21) Appl. No.: 18/437,522

(22) Filed: Feb. 9, 2024

(30) Foreign Application Priority Data
Feb. 21, 2023 (JP) 2023-025047

(51) Int. Cl. H01L 27/02; H01L 21/74; H01L 21/762; H01L 21/768

(52) U.S. Cl. CPC H01L 27/0207; H01L 21/743; H01L 21/76224; H01L 21/76816; H01L 21/76831

(57) ABSTRACT

A semiconductor device includes: a semiconductor chip including first and second main surfaces; and an element isolation portion partitioning a device region at the first main surface and including: an isolation trench at the first main surface; an isolation insulating film at an inner wall of the isolation trench; and an isolation conductor buried in the isolation trench via the isolation insulating film, wherein the isolation insulating film includes thin and thick film portions respectively having a first height from a bottom of the isolation trench and a second height from an upper end of the thin film portion up to a surface layer of the first main surface, and wherein the semiconductor chip includes an electric field concentration portion covered with the thick film portion at an intermediate portion of the isolation trench and applied with a stronger electric field than the bottom of the isolation trench.

### CROSS-REFERENCE TO RELATED APPLICATION

This application is based upon and claims the benefit of priority from Japanese Patent Application No. 2023-025047, filed on Feb. 21, 2023, the entire contents of which are incorporated herein by reference.

### TECHNICAL FIELD

The present disclosure relates to a semiconductor device and a method of manufacturing the semiconductor device.

### BACKGROUND

In the related art, there is disclosed a semiconductor device which includes an element isolation portion including a DTI (Deep Trench Isolation) structure. The element isolation portion includes a trench formed at a main surface of a semiconductor chip, an insulating film covering a side surface of the trench, and polysilicon buried in the trench with the insulating film interposed therebetween. The polysilicon is electrically connected to a high-concentration impurity region via a bottom wall of the trench.

### BRIEF DESCRIPTION OF DRAWINGS

The accompanying drawings, which are incorporated in and constitute a part of the specification, illustrate embodiments of the present disclosure.

FIG. 1 is a schematic plane view of a semiconductor device according to an embodiment of the present disclosure.

FIG. 2 is an enlarged view of region II shown in FIG. 1.

FIG. 3 is a view showing a cross-section taken along line III-III shown in FIG. 2.

FIG. 4 is an enlarged cross-sectional view of a main part of a structure shown in FIG. 3.

FIG. 5A is a view corresponding to FIG. 4, showing a portion of a process of manufacturing the semiconductor device according to the embodiment of the present disclosure.

FIG. 5B is a view showing a next step of FIG. 5A.

FIG. 5C is a view showing a next step of FIG. 5B.

FIG. 5D is a view showing a next step of FIG. 5C.

FIG. 5E is a view showing a next step of FIG. 5D.

FIG. 5F is a view showing a next step of FIG. 5E.

FIG. 5G is a view showing a next step of FIG. 5F.

FIG. 5H is a view showing a next step of FIG. 5G.

FIG. 5I is a view showing a next step of FIG. 5H.

FIG. 5J is a view showing a next step of FIG. 5I.

FIG. 5K is a view showing a next step of FIG. 5J.

FIG. 6 is a view for illustrating a modification of an isolation trench shown in FIG. 4.

FIG. 7 is a view for illustrating a modification of an isolation insulating film shown in FIG. 4.

FIG. 8 is a view for illustrating a modification of the isolation insulating film shown in FIG. 4.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings.

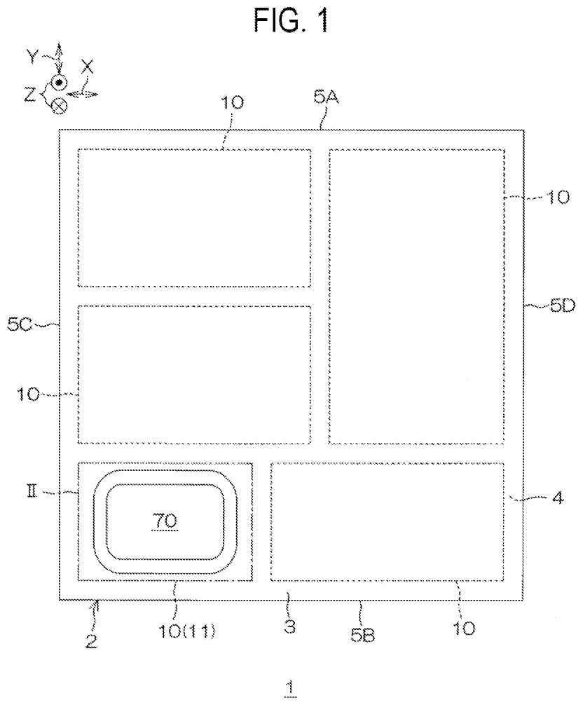

FIG. 1 is a schematic plane view of a semiconductor device 1 according to an embodiment of the present disclosure.

Referring to FIG. 1, the semiconductor device 1 includes a semiconductor chip 2 having a rectangular parallelepiped shape. In this embodiment, the semiconductor chip 2 includes a Si (silicon) chip. The semiconductor chip 2 has a first main surface 3 on one side, a second main surface 4 on the other side, and first to fourth side surfaces 5A to 5D connecting the first main surface 3 and the second main surface 4.

The first main surface 3 and the second main surface 4 are formed in a quadrangular shape in a plan view when viewed from a normal direction Z thereof (hereinafter simply referred to as “in a plan view”). The normal direction Z is also a thickness direction of the semiconductor chip 2. The first side surface 5A and the second side surface 5B extend in a first direction X along the first main surface 3 and face each other in a second direction Y that intersects (specifically, is perpendicular to) the first direction X. The third side surface 5C and the fourth side surface 5D extend in the second direction Y and face each other in the first direction X.

The semiconductor device 1 includes a plurality of device regions 10 formed at the first main surface 3. The plurality of device regions 10 are regions in which various functional devices are formed using inner regions of the semiconductor chip 2. The plurality of device regions 10 are spaced apart from the first to fourth side surfaces 5A to 5D in a plan view and are each compartmentalized at an inner portion of the first main surface 3. The number, arrangement, and shape of device regions 10 are all arbitrary, and are not limited to a specific number, arrangement, and shape.

The plurality of functional devices may each include at least one selected from the group of a semiconductor switching device, a semiconductor rectifying device, and a passive device. The semiconductor switching device may include at least one selected from the group of JFET (Junction Field Effect Transistor), MISFET (Metal Insulator Semiconductor Field Effect Transistor), BJT (Bipolar Junction Transistor), and IGBT (Insulated Gate Bipolar Junction Transistor).

The semiconductor rectifying device may include at least one selected from the group of a pn junction diode, a pin junction diode, a Zener diode, a Schottky barrier diode, and a fast recovery diode. The passive devices may include at least one selected from the group of a resistor, a capacitor, an inductor, and a fuse. The plurality of device regions 10 include at least one transistor region 11 in this embodiment.

The transistor region 11 is a region where a plurality of transistor elements are formed. A current flows in the transistor region 11 in a lateral direction of the semiconductor chip 2 when source-drain of the semiconductor device 1 is in a conductive state (on state). The transistor region 11 has, for example, a quadrangular shape in a plan view.

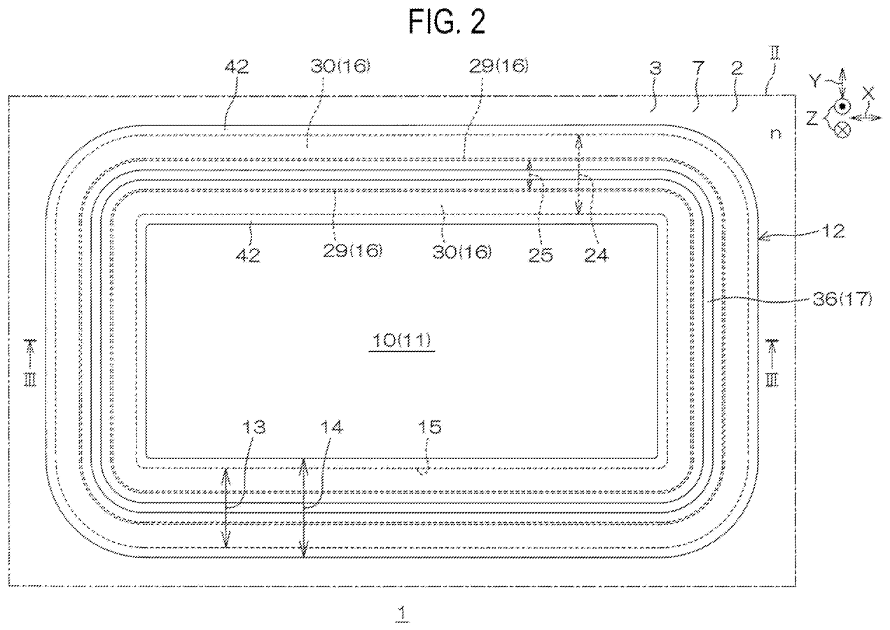

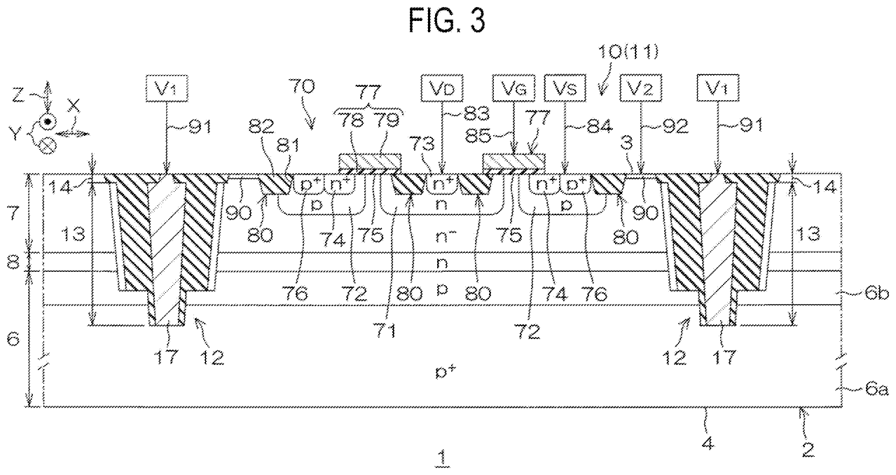

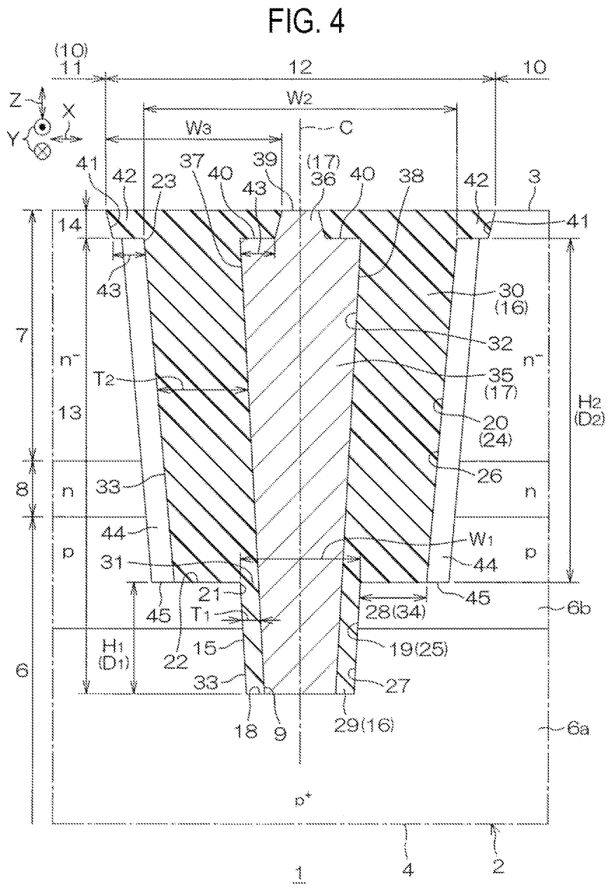

FIG. 2 is an enlarged view of region II shown in FIG. 1. FIG. 3 is a view showing a cross-section taken along line III-III shown in FIG. 2. FIG. 4 is an enlarged cross-sectional view of a main part of a structure shown in FIG. 3.

Referring to FIGS. 3 and 4, the semiconductor chip 2 includes a p-type (first conductivity type) first impurity region 6 formed at a region near the second main surface 4. The first impurity region 6 may also be referred to as a “base region.” The first impurity region 6 extends in a layered form along the second main surface 4 and is exposed from portions of the second main surface 4 and the first to fourth side surfaces 5A to 5D. The first impurity region 6 has a concentration gradient in which a p-type impurity concentration near the first main surface 3 is lower than a p-type impurity concentration near the second main surface 4. Specifically, the first impurity region 6 has a laminated structure including a p-type high-concentration region 6a and a p-type low-concentration region 6b stacked in this order from the second main surface 4. Although an outline of the second main surface 4 is not shown in the enlarged view of FIG. 4, for the sake of convenience of explanation, a place of the semiconductor chip 2 closest to the second main surface 4 is shown as the second main surface 4.

The high-concentration region 6a has a relatively high p-type impurity concentration. A p-type impurity concentration of the high-concentration region 6a may be 1×10¹⁷ cm⁻³ or more and 1×10²⁰ cm⁻³ or less. The high-concentration region 6a may contain boron (B) as the p-type impurity. The high-concentration region 6a may have a thickness of 50 μm or more and 500 μm or less. In this embodiment, the high-concentration region 6a consists of a p-type semiconductor substrate (Si substrate).

The low-concentration region 6b has a lower p-type impurity concentration than the high-concentration region 6a and is laminated on the high-concentration region 6a. A p-type impurity concentration of the low-concentration region 6b may be 1×10¹⁴ cm⁻³ or more and 1×10¹⁷ cm⁻³ or less. The low-concentration region 6b may contain boron (B) as the p-type impurity. The low-concentration region 6b has a thickness thinner than the thickness of the high-concentration region 6a. The thickness of the low-concentration region 6b may be 1 μm or more and 20 μm or less. In this embodiment, the low-concentration region 6b consists of a p-type epitaxial layer (Si epitaxial layer).

Referring to FIG. 3, the semiconductor chip 2 includes an n-type (second conductivity type) second impurity region 7 formed in a region near the first main surface 3. The second impurity region 7 extends in a layered form along the first main surface 3 and is exposed from portions of the first main surface 3 and the first to fourth side surfaces 5A to 5D. An n-type impurity concentration of the second impurity region 7 may be 1×10¹⁴ cm⁻³ or more and 1×10¹⁷ cm⁻³ or less. The second impurity region 7 may have a thickness of 5 μm or more and 30 μm or less. The second impurity region 7 may have a uniform n-type impurity concentration in the thickness direction, or may have a concentration gradient in which the n-type impurity concentration increases toward the first main surface 3. The second impurity region 7 may consist of an n-type epitaxial layer (Si epitaxial layer).

The semiconductor chip 2 includes a buried region 8 buried between the first impurity region 6 and the second impurity region 7, as an example of an n-type (second conductivity type) electric field concentration portion. In other words, the first impurity region 6, the buried region 8, and the second impurity region 7 are laminated in this order from the second main surface 4. The buried region 8 is electrically connected to the first impurity region 6 and the second impurity region 7. The buried region 8 extends in a layered form along the second impurity region 7. The buried region 8 is exposed from portions of the first to fourth side surfaces 5A to 5D. The n-type impurity concentration of the buried region 8 is higher than the n-type impurity concentration of the second impurity region 7 and may be, for example, 1×10¹⁶ cm⁻³ or more and 1×10²¹ cm⁻³ or less. The buried region 8 may have a thickness of 0.1 μm or more and 5 μm or less. The buried region 8 may consist of an n-type epitaxial layer (Si epitaxial layer).

Referring to FIGS. 2 and 3, the semiconductor chip 2 includes an element isolation portion 12 formed near the first main surface 3 and partitioning the transistor region 11. The element isolation portion 12 has an annular shape, specifically a quadrangular annular shape, in a plan view. More specifically, the element isolation portion 12 has a quadrangular annular shape having corner portions (four corners) curved in an arc-shape in a plan view.

The element isolation portion 12 includes a first trench structure 13 and a second trench structure 14 formed near the first main surface 3 with respect to the first trench structure 13.

Referring to FIG. 2, the first trench structure 13 and the second trench structure 14 overlap each other in a plan view. The second trench structure 14 is formed at a top of the first trench structure 13. Both the first trench structure 13 and the second trench structure 14 have an annular shape, specifically a quadrangular annular shape, in a plan view.

The first trench structure 13 includes an isolation trench 15, an isolation insulating film 16, and an isolation conductor 17.

Referring to FIG. 2, the isolation trench 15 is formed near the first main surface 3 so as to partition the transistor region 11. In this embodiment, the isolation trench 15 has an annular shape (in this embodiment, a quadrangular annular shape) in a plan view. More specifically, the isolation trench 15 has corner portions (four corners) curved in an arc-shape in a plan view.

Referring to FIG. 4, the isolation trench 15 penetrates the second impurity region 7 and the buried region 8 to reach the first impurity region 6. A bottom 18 of the isolation trench 15 is located in the first impurity region 6. The bottom 18 of the isolation trench 15 may also be referred to as a bottom wall of the isolation trench 15. Specifically, the isolation trench 15 extends from the first main surface 3 toward the second main surface 4 so as to reach the high-concentration region 6a of the first impurity region 6, and penetrates the second impurity region 7, the buried region 8, and the low-concentration region 6b of the first impurity region 6.

The isolation trench 15 has a step structure consisting of a plurality of portions having different widths. In this embodiment, the isolation trench 15 includes a first portion 19 formed near the bottom 18 of the isolation trench 15 and a second portion 20 formed near the first main surface 3 with respect to the first portion 19. The first portion 19 and the second portion 20 of the isolation trench 15 may also be referred to as a lower portion and an upper portion of the isolation trench 15, respectively. Further, based on the width relationship to be described later, the first portion 19 may also be referred to as a narrow portion of the isolation trench 15, and the second portion 20 may also be referred to as a wide portion of the isolation trench 15.

In this embodiment, the entire first portion 19 of the isolation trench 15 from the bottom 18 to a top 21 is formed within the first impurity region 6. The top 21 may also be a boundary against the second portion 20 of the isolation trench 15. The first portion 19 of the isolation trench 15 crosses a boundary between the high-concentration region 6a and the low-concentration region 6b in the thickness direction of the semiconductor chip 2 and may include the bottom portion 18 in the high-concentration region 6a and the top portion 21 in the low-concentration region 6b.

The first portion 19 of the isolation trench 15 is formed in a tapered shape whose width increases from the bottom 18 toward the top 21 in a cross-sectional view. The first portion 19 of the isolation trench 15 has a first width W₁ at the top 21. The first width W₁ is a width in a direction perpendicular to a direction in which the isolation trench 15 extends in a plan view. The first width W₁ may be 0.5 μm or more and 2.0 μm or less.

In this embodiment, the second portion 20 of the isolation trench 15 crosses a boundary between the first impurity region 6 and the buried region 8 and a boundary between the buried region 8 and the second impurity region 7 in the thickness direction of the semiconductor chip 2. The second portion 20 of the isolation trench 15 may have a bottom 22 in the first impurity region 6 (the low-concentration region 6b in this embodiment) and a top 23 in the second impurity region 7. The bottom 22 is integrally connected to the top 21 of the first portion 19 of the isolation trench 15. The bottom 22 may also be referred to as a bottom wall of the second portion 20 of the isolation trench 15.

The second portion 20 of the isolation trench 15 is formed to extend from the first portion 19 toward an outside of the isolation trench 15. That is, the second portion 20 of the isolation trench 15 extends out from the first portion 19 toward both the transistor region 11 and an opposite side thereof.

The second portion 20 of the isolation trench 15 is formed in a tapered shape whose width increases from the bottom 22 toward the top 23 in a cross-sectional view. The second portion 20 of the isolation trench 15 has a second width W₂ at the top 23, which is wider than the first width W₁. The second width W₂ is a width in a direction perpendicular to the direction in which the isolation trench 15 extends in a plan view. The second width W₂ may be, for example, 1.0 μm or more and 10.0 μm or less.

The isolation trench 15 may include an upper trench 24 corresponding to the second portion 20 and a lower trench 25 corresponding to the first portion 19, which is formed with a narrower width than the upper trench 24. In this embodiment, the isolation trench 15 has a two-stage trench structure including the upper trench 24 formed from the first main surface 3 toward the second main surface 4 and the lower trench 25 formed by selectively digging a portion of the semiconductor chip 2 from the bottom 22 of the upper trench 24.

Therefore, a step portion 28 in the direction along the first main surface 3 is formed between a side wall 26 of the upper trench 24 (the second portion 20) and a side wall 27 of the lower trench 25 (the first portion 19). A width of the step portion 28 corresponds to a width of the bottom 22 of the upper trench 24. In a plan view, as shown in FIG. 2, the isolation trench 15 has a double annular structure including the relatively wide upper trench 24 and the relatively narrow lower trench 25.

The isolation insulating film 16 is formed on an inner wall of the isolation trench 15. A contact opening 9 is formed in a portion on the bottom 18 of the isolation insulating film 16. The contact opening 9 exposes the first impurity region 6 into the isolation trench 15. The isolation insulating film 16 includes a thin film portion 29 and a thick film portion 30 that is thicker than the thin film portion 29. In FIG. 2, the thin film portion 29 and the thick film portion 30 covered with a buried insulator 42 (to be described later) are indicated by broken lines.

The thin film portion 29 of the isolation insulating film 16 is formed from the bottom 18 of the isolation trench 15 up to a predetermined first height H₁. More specifically, the thin film portion 29 is formed on the side wall 27 of the first portion 19 of the isolation trench 15. Therefore, the first height H₁ may correspond to a first depth D₁ of the first portion 19. The first depth D₁ is a distance from the bottom 22 of the second portion 20 of the isolation trench 15 to the bottom 18 of the first portion 19. A first thickness T₁ of the thin film portion 29 may be, for example, 100 Å or more and 1,000 Å or less.

The thick film portion 30 of the isolation insulating film 16 has a second height H₂ from an upper end 31 of the thin film portion 29 up to a surface layer of the first main surface 3. More specifically, the thick film portion 30 is formed on the side wall 26 of the second portion 20 of the isolation trench 15. As a result, the thick film portion 30 is formed to be sandwiched between the isolation conductor 17 and both the second impurity region 7 and the buried region 8 in a lateral direction along the first main surface 3. The buried region 8 is covered with the thick film portion 30 of the isolation insulating film 16 at an intermediate portion in a depth direction of the isolation trench 15.

The second height H₂ may correspond to a second depth D₂ of the second portion 20. The second depth D₂ is a distance from a bottom wall of a shallow trench 41 (to be described later) to the bottom wall (the portion 22) of the second portion 20. A second thickness T₂ of the thick film portion 30 is at least twice the first thickness T₁ of the thin film section 29, preferably at least two times and at most five times. The second thickness T₂ may be, for example, 200 Å or more and 3,500 Å or less.

In this way, the thick film portion 30 of the isolation insulating film 16 extends out from the thin film portion 29 toward both the transistor region 11 and the opposite side thereof, and is supported from below by the step portion 28 of the isolation trench 15. The isolation insulating film 16 is formed across the thin film portion 29 and the thick film portion 30 and may also include a flat inner wall 32 in contact with the isolation conductor 17 and a step-shaped outer wall 33 that is continuous through a step portion 34 formed at a boundary between the thin film portion 29 and the thick film portion 30. The step portion 34 of the isolation insulating film 16 is in contact with the step portion 28 of the isolation trench 15.

In this embodiment, the isolation insulating film 16 includes thick film portion 30 in a pair that is separated from each other in a cross-sectional view. The pair of thick film portions 30 is formed in line symmetry to a center line C extending from a center at a width direction of the bottom 18 of the isolation trench 15 so as to have the same thickness T₂.

The isolation conductor 17 is buried in the isolation trench 15 via the isolation insulating film 16. The isolation conductor 17 is polysilicon. In this embodiment, this polysilicon is doped polysilicon with a p-type (first conductivity type) impurity (for example, boron (B)) added therein. The isolation conductor 17 may be electrically connected to the first impurity region 6 exposed from the contact opening 9.

The isolation conductor 17 integrally includes a main body portion 35 and a protrusion portion 36. The main body portion 35 is a portion sandwiched between the isolation insulating films 16 in a cross-sectional view. The main body portion 35 extends over the thin film portion 29 and the thick film portion 30 of the isolation insulating film 16 and is in contact with the flat inner wall 32 of the isolation insulating film 16. As a result, the isolation conductor 17 is formed in a tapered shape by having a distance between an inner wall 37 near the transistor region 11 and an outer wall 38 on an opposite side to the inner wall 37 increase toward the first main surface 3. The protrusion portion 36 extends from an upper end of the main body portion 35 toward the first main surface 3 and is exposed from the first main surface 3. Referring to FIG. 2, an exposed surface of the protrusion portion 36 has a quadrangular annular shape in a plan view.

The isolation conductor 17 may have a first upper surface 39, which is an upper surface of the protrusion portion 36, and a second upper surface 40 formed at a lower level than the first upper surface 39. The protrusion portion 36 may be formed by selectively having a portion of a top of the isolation conductor 17 protrude. The second upper surface 40 is formed on one side and the other side of the protrusion portion 36, with the protrusion portion 36 sandwiched therebetween.

A plurality of second trench structures 14 are formed. The plurality of second trench structures 14 may also be referred to as STI (Shallow Trench Isolation) structures. The plurality of second trench structures 14 are spaced apart from each other to cover the side wall 26 of the isolation trench 15 and to expose the protrusion portion 36 of the isolation conductor 17.

The plurality of second trench structures 14 are formed at intervals from the buried region 8 toward the first main surface 3. That is, the plurality of second trench structures 14 are formed within a thickness range of the second impurity region 7. The second trench structure 14 extends along the first trench structure 13 in a plan view. In this embodiment, the second trench structure 14 is formed in an annular shape (quadrangular annular shape in this embodiment) extending along the first trench structure 13 in a plan view.

Each second trench structure 14 includes a shallow trench 41 as an example of a second isolation trench, and the buried insulator 42.

The shallow trench 41 has a third width W₃ wider than the second thickness T₂ of the thick film portion 30 of the isolation insulating film 16 in the lateral direction along the first main surface 3. The shallow trench 41 includes a lead-out portion 43 led out toward both the transistor region 11 and the opposite side thereof in a thickness direction of the thick film portion 30.

The buried insulator 42 is buried in the shallow trench 41. The buried insulator 42, at within the shallow trench 41, is in contact with the second impurity region 7, the thick film portion 30 of the isolation insulating film 16, and the isolation conductor 17. The buried insulator 42 may include at least one selected from the group of an oxide film such as silicon oxide and a nitride film such as silicon nitride.

The semiconductor chip 2 further includes an n-type sinker region 44. The sinker region 44 has a higher n-type impurity concentration than the second impurity region 7. For example, the n-type impurity concentration of the sinker region 44 may be 1.0×10¹⁷ cm⁻³ or more and 1.0×10²² cm⁻³ or less. The sinker region 44 is formed along the side wall 26 of the isolation trench 15 in a vicinity of an interface with the thick film portion 30 of the isolation insulating film 16 in the second impurity region 7. The sinker region 44 is selectively formed on the side wall 26 of the isolation trench 15, among the side walls 26 and 27 of the isolation trench 15, and is not formed on the side wall 27 of the isolation trench 15. Therefore, a lower end 45 of the sinker region 44 is formed at a depth position of the step portion 28 of the isolation trench 15.

Referring to FIG. 3, the semiconductor device 1 includes a planar gate type MISFET cell 70 as an example of a functional device formed at the transistor region 11. In FIG. 2, illustration of the MISFET cell 70 is omitted. Depending on a magnitude of a drain-source voltage of the MISFET cell 70, the MISFET cell 70 may take the form of one of a HV (High Voltage)-MISFET cell (for example, 100V or more and 1,000V or less), a MV (Middle Voltage)-MISFET cell (for example, 30V or more and 100V or less), and a LV (Low Voltage)-MISFET cell (for example, 1V or more and 30V or less). In this embodiment, an example will be described in which the MISFET cell 70 is the HV-MISFET cell, but this is not intended to limit the form of the MISFET cell 70 to the HV-MISFET cell.

In a cross-sectional view, the MISFET cell 70 includes at least one (in this embodiment, one) n-type first well region 71, at least one (in this embodiment, a plurality of) p-type second well region 72, at least one (in this embodiment, one) n-type drain region 73, at least one (in this embodiment, a plurality of) n-type source region 74, at least one (in this embodiment, a plurality of) p-type channel region 75, at least one (in this embodiment, a plurality of) p-type contact region 76, and at least one (in this embodiment, a plurality of) planar gate structure 77.

The first well region 71 is formed at a surface layer of the second impurity region 7 in the transistor region 11. The first well region 71 has a higher n-type impurity concentration than the second impurity region 7. The plurality of second well regions 72 are formed at the surface layer of the second impurity region 7 at intervals from the first well region 71 in the transistor region 11. One second well region 72 is formed at an interval from the first well region 71 on one side in the first direction X, and the other second well region 72 is formed at an interval from the first well region 71 on the other side in the first direction X.

The drain region 73 is formed at a surface layer of the first well region 71 at an interval inward from a periphery of the first well region 71. The plurality of source regions 74 are respectively formed at surface layers of the corresponding second well regions 72 at intervals inward from peripheries of the corresponding second well regions 72. The plurality of channel regions 75 are respectively formed between the second impurity region 7 and the source regions 74 at the surface layers of the corresponding second well regions 72. The plurality of contact regions 76 are respectively formed at the surface layers of the corresponding second well regions 72 at intervals inward from the peripheries of the corresponding second well regions 72. The plurality of contact regions 76 are adjacent to the corresponding source regions 74.

The plurality of planar gate structures 77 are respectively formed over the first main surface 3 so as to cover the corresponding channel regions 75, and control on/off states of the corresponding channel regions 75. In this embodiment, the plurality of planar gate structures 77 are respectively formed so as to extend over the first well region 71 and the corresponding source regions 74.

The plurality of planar gate structures 77 include a gate insulating film 78 and a gate electrode 79 laminated in this order from the first main surface 3. The gate insulating film 78 may include silicon oxide (SiO₂) or may include a tetraethyl orthosilicate (TEOS) film. Preferably, the gate insulating film 78 includes a silicon oxide film made of oxide of the semiconductor chip 2. Preferably, the gate electrode 79 includes polysilicon. The gate electrode 79 may include one or both of an n-type region and a p-type region formed in polysilicon.

Referring to FIG. 3, the semiconductor device 1 includes a plurality of third trench structures 80 formed at the first main surface 3. The plurality of third trench structures 80 may also be referred to as STI structures. In this embodiment, the plurality of third trench structures 80 are formed at intervals from each other so as to partition the drain region 73 from other regions and to partition outer edges of the plurality of second well regions 72 from other regions.

In this embodiment, the plurality of third trench structures 80 are formed at intervals from the buried region 8 toward the first main surface 3. That is, the plurality of third trench structures 80 are formed within a thickness range of the second impurity region 7.

Each of the third trench structures 80 includes a shallow trench 81 and a buried insulator 82. The shallow trench 81 is dug down from the first main surface 3 toward the second main surface 4. The buried insulator 82 is buried in the shallow trench 81. The buried insulator 82 may include at least one selected from the group of of silicon oxide and silicon nitride.

In the transistor region 11, a drain potential V_{D} is applied to the drain region 73 via a drain contact electrode 83. In FIG. 3, the drain contact electrode 83 is shown in a simplified manner by an arrow. The drain potential V_{D} is a positive device potential in the transistor region 11. A source potential V_{S} lower than the drain potential V_{D} is applied to the source region 74 via a source contact electrode 84. In FIG. 3, the source contact electrode 84 is shown in a simplified manner by an arrow. A gate potential V_{G} is applied to the gate electrode 79 via a gate contact electrode 85. In FIG. 3, the gate contact electrode 85 is shown in a simplified manner by an arrow.

A first potential V₁ is applied to the isolation conductor 17 via a contact electrode 91. In FIG. 3, the contact electrode 91 is shown in a simplified manner by an arrow. The first potential V₁ applied to the isolation conductor 17 is applied to the high-concentration region 6a via the isolation conductor 17. As a result, the high-concentration region 6a is fixed at a same potential as the isolation conductor 17. The first potential V₁ is preferably a potential equal to or lower than the drain potential V_{D} (preferably lower than the drain potential V_{D}). That is, the first potential V₁ is preferably lower than a maximum device potential. The first potential V₁ may be a reference potential serving as a reference for circuit operation or a ground potential. Preferably, the first potential V₁ is the ground potential.

A second potential V₂ is applied to a back gate contact region 90, which is formed between the first trench structure 13 and the transistor region 11 in the semiconductor chip 2, via a second contact electrode 92. In FIG. 3, the second contact electrode 92 is shown in a simplified manner by an arrow. The second potential V₂ is preferably a potential equal to or lower than the drain potential V_{D} (preferably lower than the drain potential V_{D}). Preferably, the second potential V₂ is lower than the maximum device potential. The second potential V₂ may be equal to or higher than the first potential V₁ (V₁≤V₂). The second potential V₂ may also exceed the first potential V₁ (V₁<V₂). The second potential V₂ may be a reference potential or a ground potential.

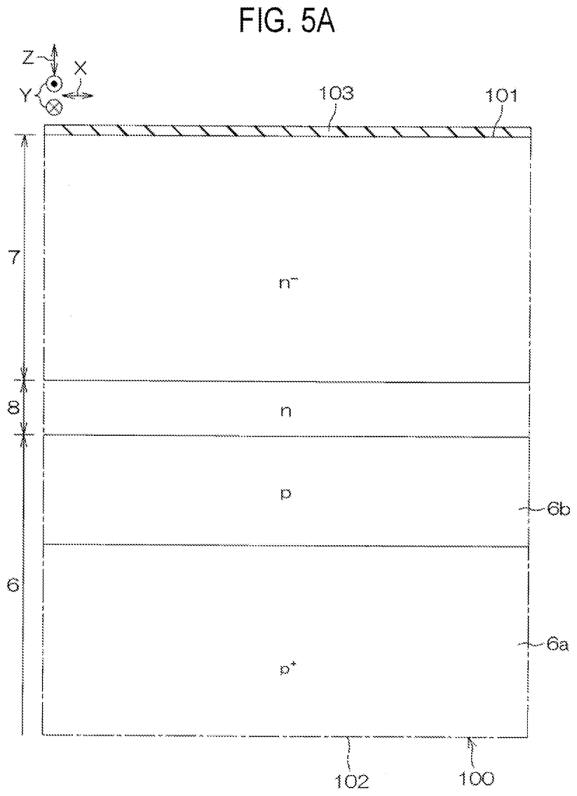

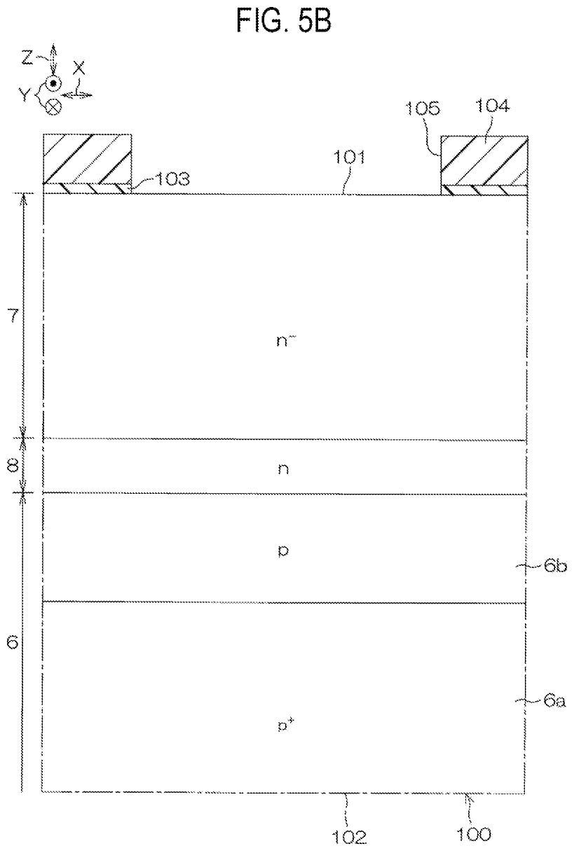

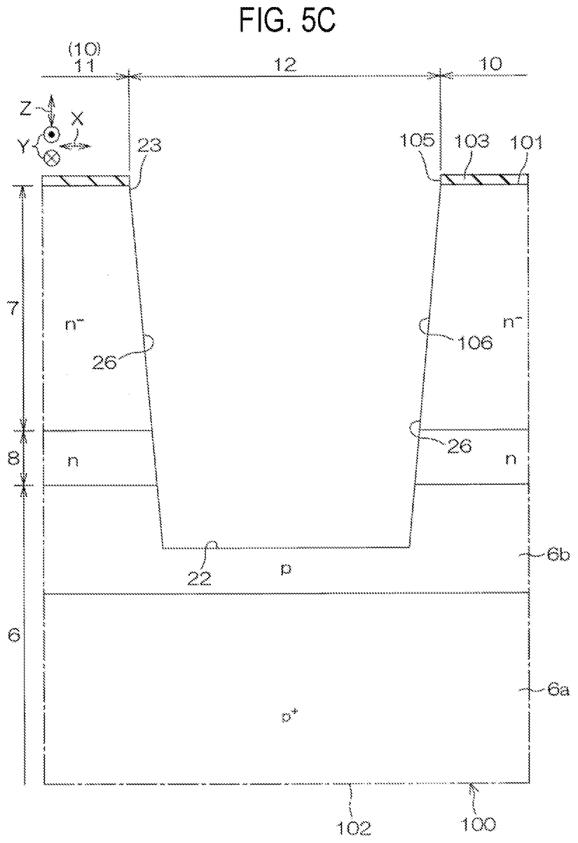

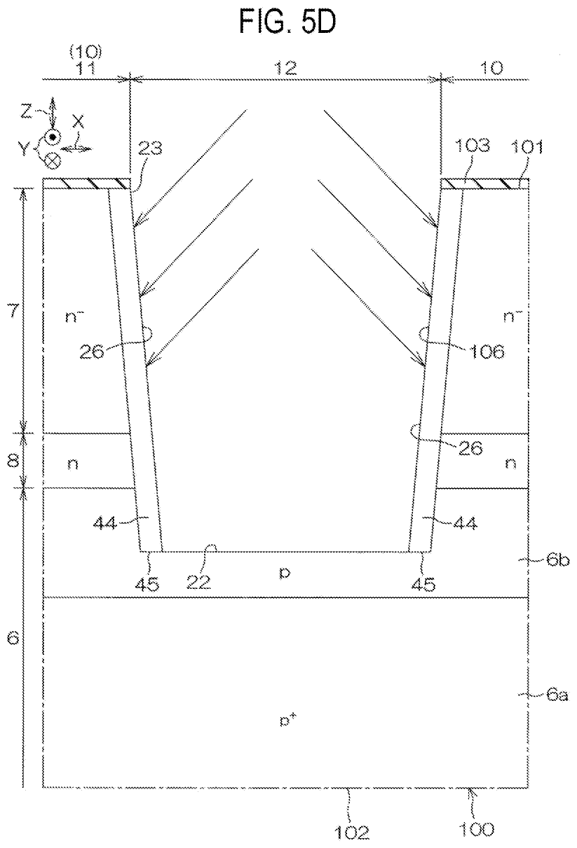

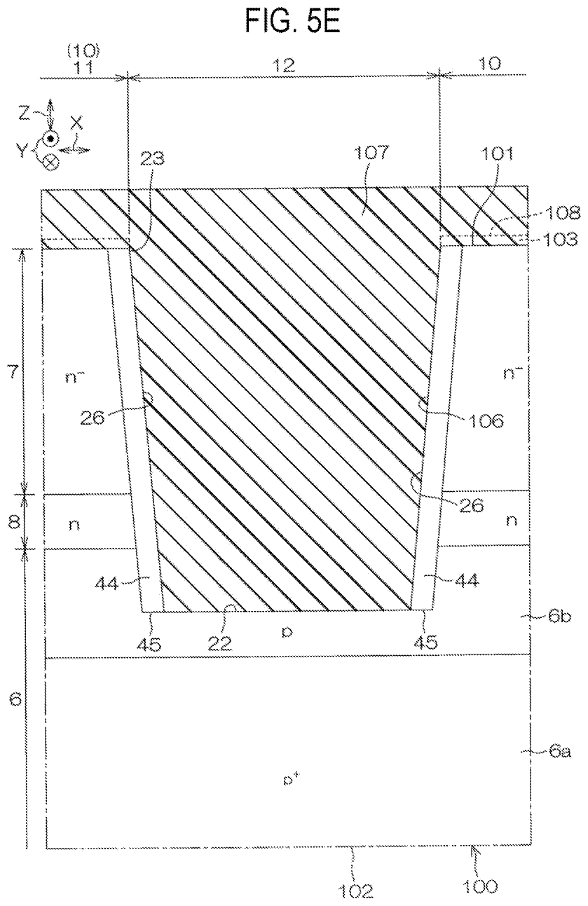

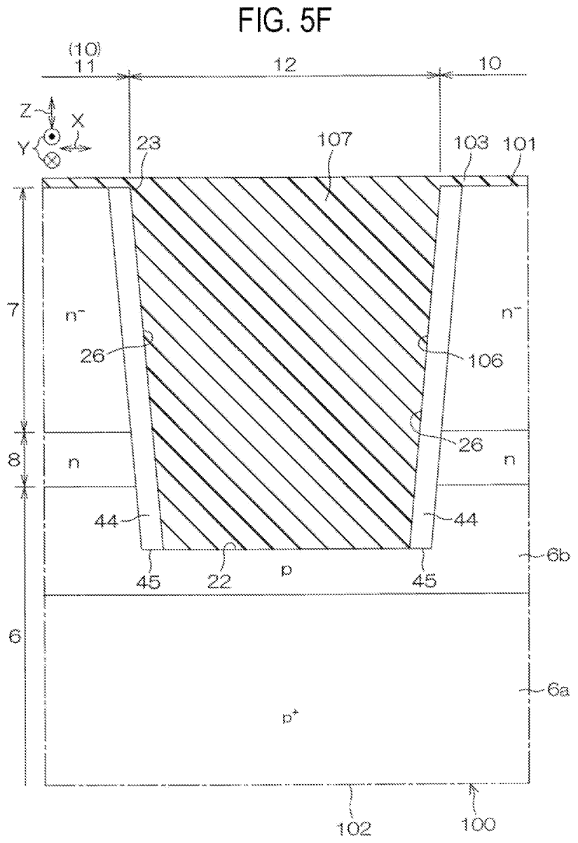

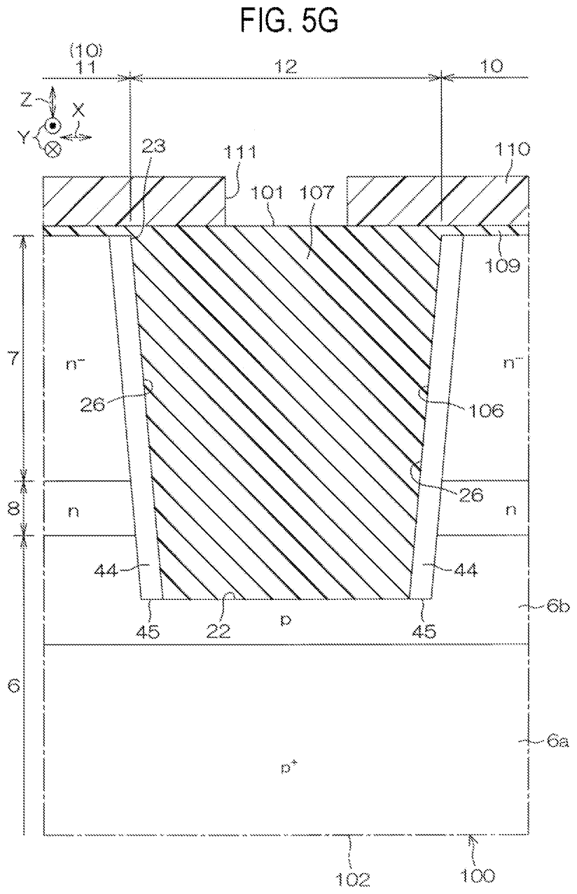

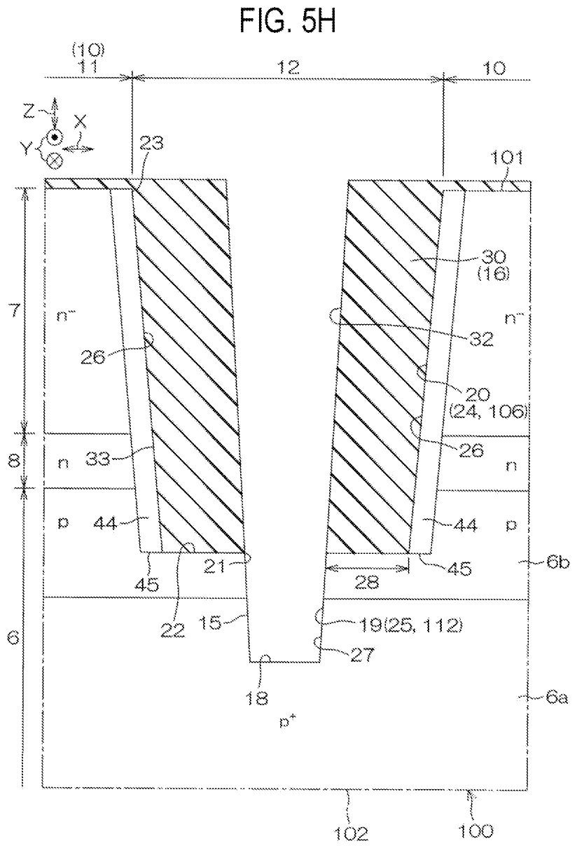

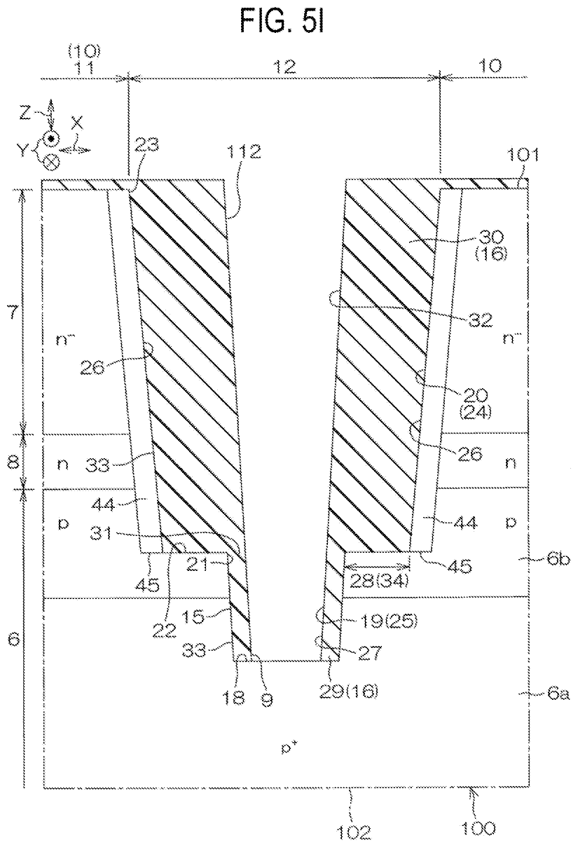

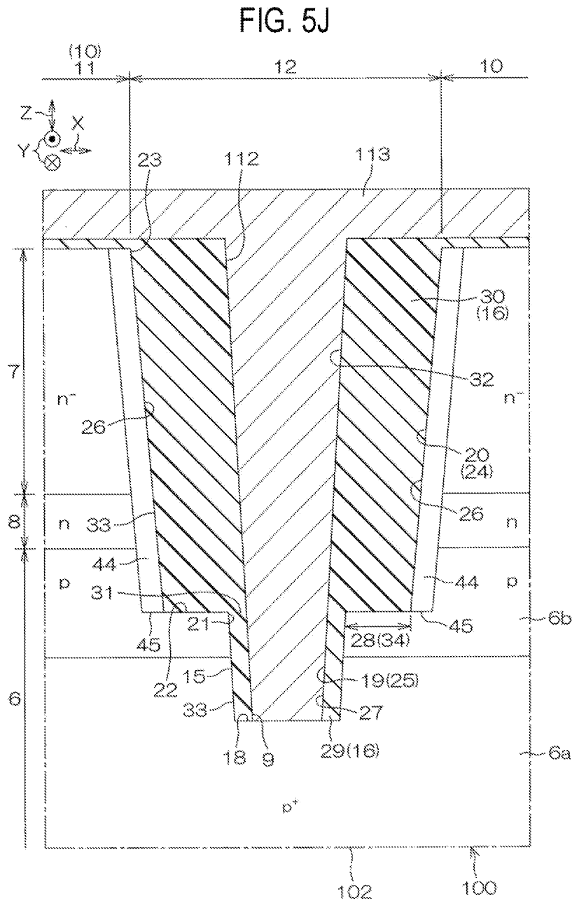

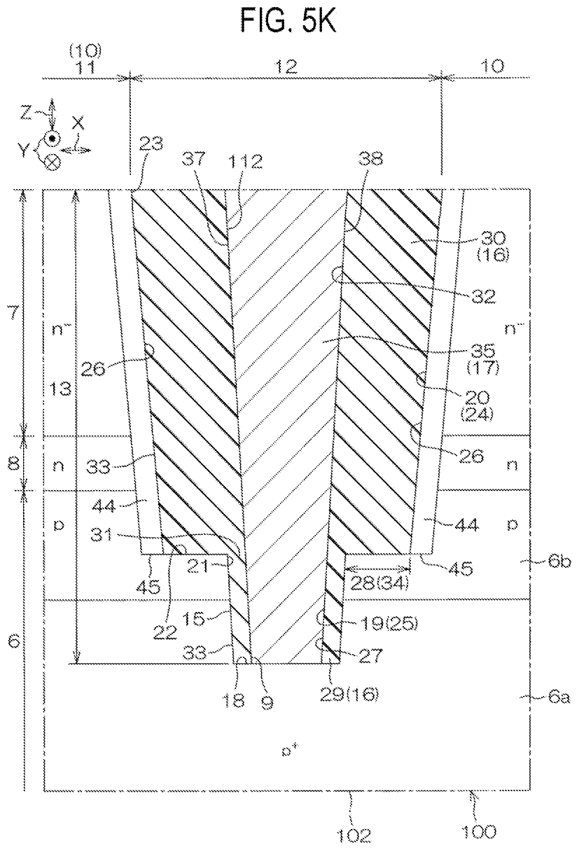

FIGS. 5A to 5K are views corresponding to FIG. 4, showing portions of a process of manufacturing the semiconductor device 1 according to the embodiment of the present disclosure.

Referring to FIG. 5A, in order to manufacture the semiconductor device 1, a semiconductor wafer 100 that becomes a base of the semiconductor chip 2 is prepared. The semiconductor wafer 100 has a first wafer main surface 101 corresponding to the first main surface 3 and a second wafer main surface 102 corresponding to the second main surface 4. Although an outline of the second wafer main surface 102 is not shown in the enlarged view of FIG. 5A, for the sake of convenience of explanation, a place of the semiconductor wafer 100 closest to the second wafer main surface 102 is shown as the second wafer main surface 102.

The semiconductor wafer 100 includes the first impurity region 6, the second impurity region 7, and the buried region 8. The first impurity region 6 includes the high-concentration region 6a and the low-concentration region 6b. The high-concentration region 6a consists of a p-type semiconductor substrate. The low-concentration region 6b consists of a p-type epitaxial layer, which is laminated on the semiconductor substrate, by an epitaxial growth method.

Next, a mask 103 is formed over the entire first wafer main surface 101 of the semiconductor wafer 100. The mask 103 may be a hard mask made of, for example, silicon oxide (SiO₂). The mask 103 is formed by, for example, a thermal oxidation method or a CVD method.

Next, referring to FIG. 5B, a resist 104 is formed over the mask 103. The resist 104 has an opening 105 having a shape corresponding to the upper trench 24 (the second portion 20) of the isolation trench 15. By selectively etching the mask 103 through the opening 105, the opening 105 penetrates the mask 103 to reach the first wafer main surface 101.

Next, referring to FIG. 5C, the semiconductor wafer 100 is selectively etched through the opening 105 of the mask 103. As a result, an annular first trench 106 is formed at the first wafer main surface 101 to partition the transistor region 11 (the device region 10). The first trench 106 penetrates the second impurity region 7 and the buried region 8 to expose the low-concentration region 6b. The first trench 106 is formed in a tapered shape whose width increases from the bottom 22 toward the first wafer main surface 101 in a cross-sectional view. The etching method may be a dry etching method and/or a wet etching method.

The first trench 106 has a shape that becomes a base of the upper trench 24 (the second portion 20) of the isolation trench 15, and has the side wall 26 and the bottom 22. At this stage, the bottom 22 is not divided at a region between the side wall 26 on one side and the side wall 26 on the other side in a cross-sectional view, and connects the pair of side walls 26 at a lower end of the first trench 106.

Next, referring to FIG. 5D, an n-type impurity is implanted into an inner wall of the first trench 106. The n-type impurity is implanted obliquely at a certain angle with respect to the first wafer main surface 101. As a result, the sinker region 44 having a higher concentration than the second impurity region 7 is formed. The sinker region 44 is formed with the mask 103 remaining over the first wafer main surface 101. This may prevent an entire surface layer of the first wafer main surface 101 from being transformed into an n-type impurity region having a same concentration as the sinker region 44.

Next, referring to FIG. 5E, a first insulating material 107, which becomes a base of the thick film portion 30 of the isolation insulating film 16, is deposited on the first wafer main surface 101 via the mask 103. The first insulating material 107 may be silicon oxide (SiO₂) or tetraethyl orthosilicate (TEOS). The deposition of the first insulating material 107 continues until the first trench 106 is filled. The first insulating material 107 may be formed, for example, by thermally oxidizing the inner wall of the first trench 106 to form a thermal oxide film in a surface layer of the inner wall and then backfilling the first trench 106 with SiO₂ by depositing TEOS with a VCD method. Note that in FIG. 5E, a boundary 108 between the mask 103 and the first insulating material 107 is indicated by a broken line because the boundary may not be visually recognizable in case when the mask 103 and the first insulating material 107, which are made of SiO₂, are integrated.

Next, referring to FIG. 5F, unnecessary portions of the deposited first insulating material 107 are removed. This process includes a step of removing the first insulating material 107 by a grinding method until the mask 103 is exposed. The grinding method may be a CMP (Chemical Mechanical Polishing) method.

Next, referring to FIG. 5G, the mask 103 is removed and another mask 109 is newly formed over the entire first wafer main surface 101. The mask 109 may be a hard mask made of, for example, silicon oxide (SiO₂). The mask 109 is formed by, for example, a thermal oxidation method or a VCD method. Next, a resist 110 is formed on the mask 109. The resist 110 has an opening 111 having a shape corresponding to the lower trench 25 (the first portion 19) of the isolation trench 15.

Next, referring to FIG. 5H, the first insulating material 107 is selectively etched through the opening 111 of the mask 109. The etching of the first insulating material 107 continues until the bottom 22 of the first trench 106 is exposed. As a result, the first insulating material 107 is separated, and the thick film portion 30 of the isolation insulating film 16 is formed. Next, the bottom 22 of the first trench 106 exposed between the thick film portions 30 is further etched. As a result, a second trench 112 having a width narrower than that of the first trench 106 is formed, and the isolation trench 15 having a two-stage trench structure is formed. At this stage, a portion of the first impurity region 6 is exposed at a side wall of the first portion 19 of the isolation trench 15.

Next, referring to FIG. 5I, the thin film portion 29 of the isolation insulating film 16 is formed on an inner wall of the first portion 19 of the isolation trench 15. The thin film portion 29 may be formed, for example, by thermal oxidation of the inner wall of the first portion 19 of the isolation trench 15. As a result, the isolation insulating film 16 in which the thin film portion 29 and the thick film portion 30 are integrated is obtained. Next, the contact opening 9 is formed by selectively etching the thin film portion 29 on the bottom 18 of the isolation trench 15. The second trench 112 is defined by the flat inner wall 32 and the bottom 18 and has a tapered shape whose width increases from the bottom 18 toward the first wafer main surface 101.

Next, referring to FIG. 5J, a polysilicon material 113, which becomes a base of the isolation conductor 17, is deposited on the first wafer main surface 101. In this embodiment, the polysilicon material 113 includes doped polysilicon with a p-type (first conductivity type) impurity added therein. The deposition of the polysilicon material 113 continues until the second trench 112 is filled. The polysilicon material 113 may be deposited by a VCD method.

Next, referring to FIG. 5K, unnecessary portions of the deposited polysilicon material 113 are removed. This process includes a step of removing the polysilicon material 113 by a grinding method until the mask 109 is exposed. The grinding method may be a CMP (Chemical Mechanical Polishing) method. As a result, the isolation conductor 17 is formed by the polysilicon material 113 remaining in the second trench 112. As a result, the first trench structure 13 is formed. Of course, in this step, an etching method (wet etching method and/or dry etching method) may be employed instead of the grinding method. After the isolation conductor 17 is formed, the mask 109 is removed.

Next, the shallow trench 41 is formed, and the buried insulator 42 is buried in the shallow trench 41. The protrusion portion 36 of the isolation conductor 17 is formed by partially removing a top of the isolation conductor 17 via etching when forming the shallow trench 41. Next, a functional device such as the MISFET cell 70 is formed at the first wafer main surface 101 of the semiconductor wafer 100. Thereafter, the semiconductor wafer 100 is divided into a plurality of semiconductor devices 1 through a process of forming elements necessary for the semiconductor devices 1. As a result, chips of the semiconductor devices 1 are obtained.

As described above, according to the semiconductor device 1, the isolation insulating film 16 of the first trench structure 13 includes the thick film portion 30. The thick film portion 30 is formed to be sandwiched between the buried region 8 and the isolation conductor 17 in the lateral direction along the first main surface 3.

The buried region 8 covered with the thick film portion 30 is sandwiched between the p-type first impurity region 6 and the low-concentration n-type second impurity region 7 and is more likely for an electric field to concentrate on the buried region 8 than on the bottom 18 of the isolation trench 15. This is because an equipotential line is bent into an L-shape in a cross-section at a boundary between the isolation conductor 17 (having the same potential as the first impurity region 6), connected to the p-type first impurity region 6 and extending in the normal direction of the first main surface 3, and the n-type second impurity region 7 or the buried region 8, formed along the first main surface 3 and intersecting the isolation conductor 17. The electric field tends to concentrate at a corner of the L-shaped portion of the equipotential line. Therefore, if electric field concentration occurs at the side wall 26 of the isolation trench 15 at a portion between the buried region 8 and the isolation conductor 17, a breakdown voltage of the semiconductor device 1 may decrease. Therefore, by providing the thick film portion 30 covering the buried region 8, it is possible to prevent the isolation insulating film 16 from being destroyed even if the electric field is concentrated. As a result, the breakdown voltage of the semiconductor chip 2 in the lateral direction along the first main surface 3 may be improved.

Further, the thick film portion 30 is formed from the bottom (the bottom 18 of the first portion 19) of the isolation trench 15 to the top (the top 23 of the second portion 20) thereof and covers the top portion 23. Since the top 23 of the isolation trench 15 has a corner at which the first main surface 3 and the side wall 26 intersect, the electric field tends to concentrate thereon. Since this top 23 is also covered with the thick film portion 30, a breakdown voltage of the isolation insulating film 16 at the top 23 of the isolation trench 15 may also be improved.

Further, the formation of the thick film portion 30 only requires preparation of masks for the first trench 106 and the second trench 112 and addition of an etching process via the masks, so the manufacturing process of the semiconductor device 1 may also be prevented from getting more complicated.

Although the embodiments of the present disclosure have been described, the present disclosure may be implemented in other forms.

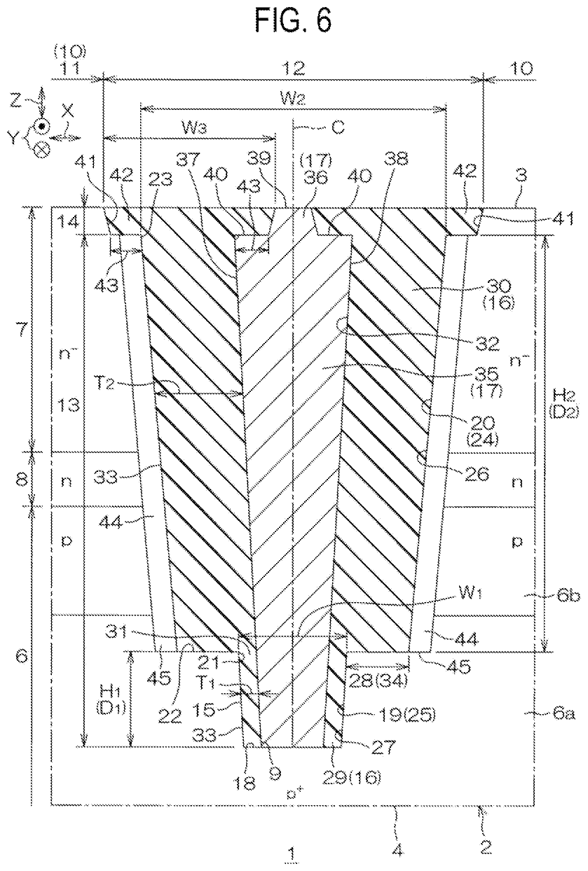

For example, referring to FIG. 6, the upper trench 24 may reach the high-concentration region 6a of the first impurity region 6 from the first main surface 3. As a result, the bottom 22 of the second portion 20 of the isolation trench 15 may be located in the high-concentration region 6a, and the lower end 45 of the thick film portion 30 of the isolation insulating film 16 may be located within the high-concentration region 6a (in this embodiment, the p-type semiconductor substrate).

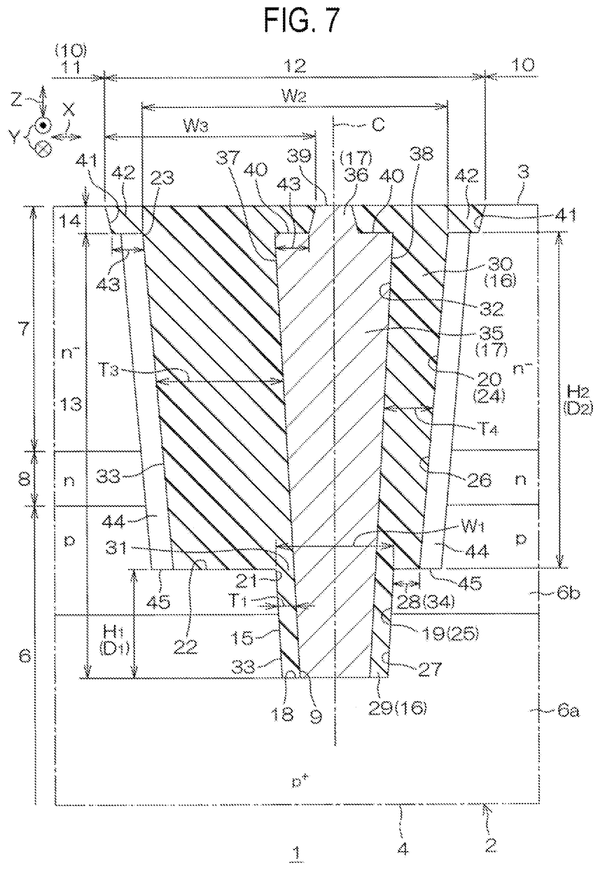

For example, referring to FIG. 7, the isolation insulating film 16 may be formed in non-line symmetry to the center line C. In FIG. 7, it is assumed that an HV-MISFET cell is mounted at the device region 10 on a left side of the diagram and an LV-MISFET cell is mounted at the device region 10 on a right side of the diagram. In this case, by setting a third thickness T₃ of the thick film portion 30 on the left side of the diagram to be thicker than a fourth thickness T₄ of the thick film portion 30 on the right side of the diagram, the isolation insulating film 16 (the thick film portion 30) may be provided with an appropriate thickness depending on a breakdown voltage of each device region 10.

In order to form the thick film portions 30 having different thicknesses, in the step of FIG. 5H, the second trench 112 may be formed such that a center of the second trench 112 in a width direction is located at a position biased towards either one of the device regions 10 on one side or the other side, with respect to a center of the bottom 22 of the first trench 106 in the width direction.

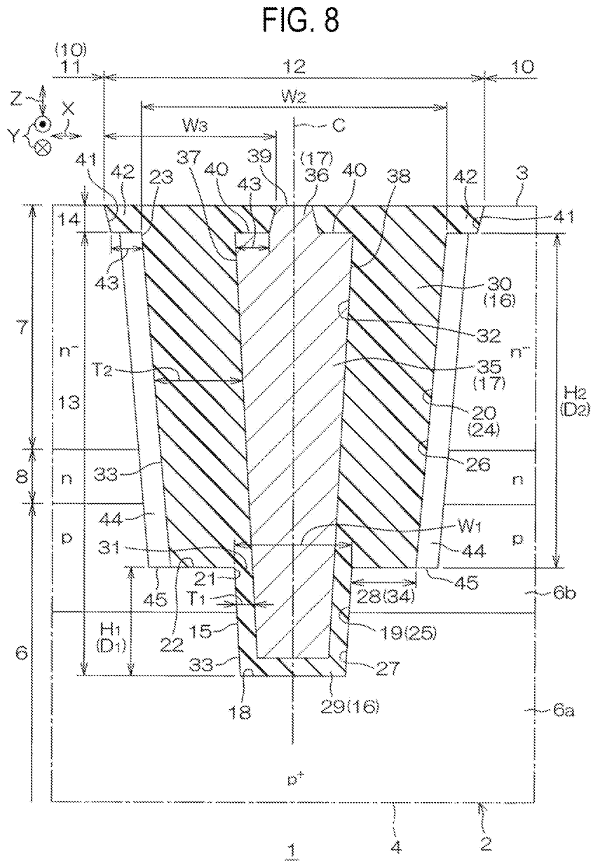

Regarding a modification of the isolation insulating film 16, for example, referring to FIG. 8, the contact opening 9 may not be formed at the thin film portion 29. In this case, the isolation conductor 17 is insulated from the first impurity region 6 (in this embodiment, the high-concentration region 6a) by the thin film portion 29.

As an example, in the above-described embodiments, the buried region 8 has been shown as an example of the electric field concentration portion in the semiconductor chip 2, but a target for improving the breakdown voltage by covering the thick film portion 30 is not limited to the buried region 8. For example, the target may be the top 23 of the second portion 20 of the isolation insulating film 16.

As an example, although the element isolation portion 12 has been described as one that annularly surrounds one transistor region 11 and isolates it from another device region 10, it may also define a boundary between two adjacent transistor regions 11.

As an example, a configuration may be adopted in which the conductivity type of each semiconductor portion of the semiconductor device 1 is reversed. For example, in the semiconductor device 1, the p-type (first conductivity type) portion may be n-type, and the n-type (second conductivity type) portion may be p-type.

As described above, the embodiments of the present disclosure are illustrative in all respects and should not be construed as limiting, and are intended to include changes in all respects.

The features described below may be extracted from the description of the present disclosure and the drawings.

### Supplementary Note 1-1

A semiconductor device (1) including:
a semiconductor chip (2) including a first main surface (3) and a second main surface (4) opposite to the first main surface; and
an element isolation portion (12) formed at the first main surface (3) of the semiconductor chip (2) and partitioning a device region (10, 11),
wherein the element isolation portion (12) includes:
an isolation trench (15) formed at the first main surface (3) of the semiconductor chip (2);
an isolation insulating film (16) formed at an inner wall (26, 27) of the isolation trench (15); and
an isolation conductor (17) buried in the isolation trench (15) via the isolation insulating film (16),
a thin film portion (29) formed from a bottom (18) of the isolation trench (15) up to a predetermined first height (H₁); and
a thick film portion (30) that has a second height (H₂) from an upper end (31) of the thin film portion (29) up to a surface layer of the first main surface (3) and is thicker than the thin film portion (29), and
wherein the semiconductor chip (2) includes an electric field concentration portion (8) that is covered with the thick film portion (30) of the isolation insulating film (16) at an intermediate portion in a depth direction of the isolation trench (15) and is applied with an electric field stronger than an electric field applied to the bottom (18) of the isolation trench (15).

According to this configuration, the thick film portion (30) of the isolation insulating film (16) covers the electric field concentration portion (8) in the lateral direction along the first main surface (3). When electric field concentration occurs in the electric field concentration portion (8) at the side wall (26, 27) of the isolation trench (15), there is a possibility that the breakdown voltage of the semiconductor device (1) decreases. Therefore, by providing the thick film portion (30) that covers the electric field concentration portion (8), it is possible to prevent the isolation insulating film (16) from being destroyed even if the electric field concentration occurs. As a result, it is possible to improve the breakdown voltage in the lateral direction along the first main surface (3) of the semiconductor chip (2).

### Supplementary Note 1-2

The semiconductor device (1) of Supplementary Note 1-1, wherein the isolation trench (15) includes:
a first portion (19) that is covered with the thin film portion (29) of the isolation insulating film (16) and has a first width (W₁); and
a second portion (20) that is formed to extend from the first portion (19) toward an outside of the isolation trench (15), is covered with the thick film portion (30) of the isolation insulating film (16), and has a second width (W₂) wider than the first width (W₁).

### Supplementary Note 1-3

The semiconductor device (1) of Supplementary Note 1-1 or 1-2, wherein the isolation insulating film (16) further includes:
a flat inner wall (32) that is formed across the thin film portion (29) and the thick film portion (30) in the depth direction of the isolation trench (15) and in contact with the isolation conductor (17);
and a step-shaped outer wall (33) that is continuous through a step portion (34) formed at a boundary between the thin film portion (29) and the thick film portion (30).

### Supplementary Note 1-4

The semiconductor device (1) of any one of Supplementary Notes 1-1 to 1-3, wherein a thickness (T₂) of the thick film portion (30) of the isolation insulating film (16) is at least twice a thickness (T₁) of the thin film portion (29) of the isolation insulating film (16).

### Supplementary Note 1-5

The semiconductor device (1) of any one of Supplementary Notes 1-1 to 1-4, wherein the thickness (T₁) of the thin film portion (29) of the isolation insulating film (16) is 100 Å or more and 1,000 Å or less, and the thickness (T₂) of the thick film portion (30) of the isolation insulating film (16) is 200 Å or more and 3,500 Å or less.

### Supplementary Note 1-6

The semiconductor device (1) of any one of Supplementary Notes 1-1 to 1-5, wherein the semiconductor chip (2) further includes:
a first impurity region (6) of a first conductivity type formed at the second main surface (4);
a second impurity region (7) of a second conductivity type formed at the first main surface (3); and
a buried region (8) of the second conductivity type as the electric field concentration portion (8) buried between the first impurity region (6) and the second impurity region (7),
wherein the isolation trench (15) penetrates from the first main surface (3) through the second impurity region (7) and the buried region (8) and has the bottom (18) in the first impurity region (6), and
wherein the thick film portion (30) of the isolation insulating film (16) is formed to be sandwiched between the isolation conductor (17) and both the second impurity region (7) and the buried region (8) in a lateral direction along the first main surface (3).

### Supplementary Note 1-7

The semiconductor device (1) of Supplementary Note 1-6, wherein the semiconductor chip (2) further includes a sinker region (44) of the second conductivity type that is formed along a side wall (26) of the isolation trench (15) in a vicinity of an interface with the thick film portion (30) of the isolation insulating film (16) in the second impurity region (17) and has a concentration higher than a concentration of the second impurity region (7).

### Supplementary Note 1-8

The semiconductor device (1) of Supplementary Note 1-6 or 1-7, wherein the first impurity region (6) includes:
a substrate (6a) of the first conductivity type; and
an epitaxial layer (6b) of the first conductivity type having a concentration lower than a concentration of the substrate (6a), and
wherein a lower end (45) of the thick film portion (30) of the isolation insulating film (16) is located within the substrate (6a).

### Supplementary Note 1-9

The semiconductor device (1) of any one of Supplementary Notes 1-6 to 1-8, wherein the isolation insulating film (16) further includes an opening (9) at the bottom (18) of the isolation trench (15), and
wherein the isolation conductor (17) is electrically connected to the first impurity region (6) via the opening (9).

### Supplementary Note 1-6

The semiconductor device (1) of any one of Supplementary Notes 1-1 to 1-9, wherein the isolation insulating film (16) further includes the thick film portion (30) in a pair that is separated from each other in a cross-sectional view, and
wherein the pair of thick film portion (30) is formed in line symmetry to a center line (C) extending from a center at a width direction of the bottom (18) of the isolation trench (15), so as to have a same thickness (T₂).

### Supplementary Note 1-6

The semiconductor device (1) of any one of Supplementary Notes 1-1 to 1-9, wherein the isolation insulating film (16) further includes the thick film portion (30) in a pair that is separated from each other in a cross-sectional view, and
wherein the pair of thick film portion (30) is formed in non-line symmetry to a center line (C) extending from a center at a width direction of the bottom (18) of the isolation trench (15), so as to have different thicknesses (T₃, T₄).

### Supplementary Note 1-12

The semiconductor device (1) of any one of Supplementary Notes 1-1 to 1-11, further including:
a second isolation trench (41) that is formed at the surface layer of the first main surface (3) of the semiconductor chip (2) to be continuous with the isolation trench (15) and is shallower than the isolation trench (15); and

a buried insulator (42) that is buried in the second isolation trench (41) and is integrated with the thick film portion (30) of the isolation insulating film (16).

### Supplementary Note 1-13

The semiconductor device (1) of Supplementary Note 1-12, wherein the second isolation trench (41) has a width (W₃) wider than a thickness (T₂) of the thick film portion (30) of the isolation insulating film (16) in a lateral direction along the first main surface (3).

### Supplementary Note 1-14

A method of manufacturing a semiconductor device (1), including:
forming an annular first trench (106) to partition a device region (10, 11) at a first main surface (101) of a semiconductor wafer (100) including the first main surface (101) and a second main surface (102) opposite to the first main surface (101);
burying a first insulator (107) in the first trench (106);
forming a second trench (112) having a narrower width than the first trench (106) by selectively etching the first insulator (107) and a portion of the semiconductor wafer (100) below the first insulator (107), and forming a thick film insulation portion (30) made of the first insulator (107) remaining on a side wall of the second trench (112);
forming a thin film insulation portion (29), which is thinner than the thick film insulation portion (30), on an inner wall of the second trench (112) of the portion of the semiconductor wafer (100) so that an isolation insulation film (16) in which the thick film insulation portion (30) and the thin film insulation portion (29) are integrated is formed; and
forming an isolation conductor (17) by burying a conductive material (113) in the second trench (112).

According to this method, it is possible to provide the semiconductor device (1) that may improve the breakdown voltage in the lateral direction along the first main surface (101) of the semiconductor chip (2). Further, the formation of the thick film insulation portion (30) only requires preparation of masks for the first trench (106) and the second trench (112) and addition of an etching process via the masks, so the manufacturing process of the semiconductor device (1) may also be prevented from getting more complicated.

### Supplementary Note 1-15

The method of Supplementary Note 1-14, wherein the semiconductor wafer (100) includes:

a first impurity region (6) of a first conductivity type formed at the second main surface (102);

a second impurity region (7) of a second conductivity type formed at the first main surface (101); and a buried region (8) of the second conductivity type buried between the first impurity region (6) and the second impurity region (7), wherein the first trench (106) is formed from the first main surface (101) through the second impurity region (7) and the buried region (8) so that a bottom (18) of the first trench (106) reaches the first impurity region (6).

### Supplementary Note 1-16

The method of Supplementary Note 1-15, further including: forming the sinker region (44) of a second conductivity type, which has a concentration higher than a concentration of the second impurity region (7), along a side wall of the first trench (106) in the second impurity region (7), by implanting a second conductivity type impurity into an inner wall (26, 27) of the first trench (106), before burying the first insulator (107).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor chip including a first main surface and a second main surface opposite to the first main surface; and
an element isolation portion formed at the first main surface of the semiconductor chip and partitioning a device region,
wherein the element isolation portion includes:
an isolation trench formed at the first main surface of the semiconductor chip;
an isolation insulating film formed at an inner wall of the isolation trench; and
an isolation conductor buried in the isolation trench via the isolation insulating film, wherein the isolation insulating film includes:
a thin film portion formed from a bottom of the isolation trench up to a predetermined first height; and
a thick film portion that has a second height from an upper end of the thin film portion up to a surface layer of the first main surface and is thicker than the thin film portion, and
wherein the semiconductor chip includes an electric field concentration portion that is covered with the thick film portion of the isolation insulating film at an intermediate portion in a depth direction of the isolation trench and is applied with an electric field stronger than an electric field applied to the bottom of the isolation trench.

2. The semiconductor device of claim 1, wherein the isolation trench includes:
a first portion that is covered with the thin film portion of the isolation insulating film and has a first width; and
a second portion that is formed to extend from the first portion toward an outside of the isolation trench, is covered with the thick film portion of the isolation insulating film, and has a second width wider than the first width.

3. The semiconductor device of claim 2, wherein the isolation insulating film further includes:
a flat inner wall that is formed across the thin film portion and the thick film portion in the depth direction of the isolation trench and in contact with the isolation conductor; and
a step-shaped outer wall that is continuous through a step portion formed at a boundary between the thin film portion and the thick film portion.

4. The semiconductor device of claim 3, wherein a thickness of the thick film portion of the isolation insulating film is at least twice a thickness of the thin film portion of the isolation insulating film.

5. The semiconductor device of claim 4, wherein the thickness of the thin film portion of the isolation insulating film is 100 Å or more and 1,000 Å or less, and the thickness of the thick film portion of the isolation insulating film is 200 Å or more and 3,500 Å or less.

6. The semiconductor device of claim 1, wherein the semiconductor chip further includes:
a first impurity region of a first conductivity type formed at the second main surface;
a second impurity region of a second conductivity type formed at the first main surface; and
a buried region of the second conductivity type as the electric field concentration portion buried between the first impurity region and the second impurity region,
wherein the isolation trench penetrates from the first main surface through the second impurity region and the buried region and has the bottom in the first impurity region, and wherein the thick film portion of the isolation insulating film is formed to be sandwiched between the isolation conductor and both the second impurity region and the buried region in a lateral direction along the first main surface.

7. The semiconductor device of claim 6, wherein the semiconductor chip further includes a sinker region of the second conductivity type that is formed along a side wall of the isolation trench in a vicinity of an interface with the thick film portion of the isolation insulating film in the second impurity region and has a concentration higher than a concentration of the second impurity region.

8. The semiconductor device of claim 6, wherein the first impurity region includes:
a substrate of the first conductivity type; and
an epitaxial layer of the first conductivity type having a concentration lower than a concentration of the substrate, and
wherein a lower end of the thick film portion of the isolation insulating film is located within the substrate.

9. The semiconductor device of claim 6, wherein the isolation insulating film further includes an opening at the bottom of the isolation trench, and
wherein the isolation conductor is electrically connected to the first impurity region via the opening.

10. The semiconductor device of claim 1, wherein the isolation insulating film further includes the thick film portion in a pair that is separated from each other in a cross-sectional view, and
wherein the pair of thick film portion is formed in line symmetry to a center line extending from a center at a width direction of the bottom of the isolation trench, so as to have a same thickness.

11. The semiconductor device of claim 1, wherein the isolation insulating film further includes the thick film portion in a pair that is separated from each other in a cross-sectional view, and
wherein the pair of thick film portion is formed in non-line symmetry to a center line extending from a center at a width direction of the bottom of the isolation trench, so as to have different thicknesses.

12. The semiconductor device of claim 1, further comprising:
a second isolation trench that is formed at the surface layer of the first main surface of the semiconductor chip to be continuous with the isolation trench and is shallower than the isolation trench; and
a buried insulator that is buried in the second isolation trench and is integrated with the thick film portion of the isolation insulating film.

13. The semiconductor device of claim 12, wherein the second isolation trench has a width wider than a thickness of the thick film portion of the isolation insulating film in a lateral direction along the first main surface.

14. A method of manufacturing a semiconductor device, comprising:
forming an annular first trench to partition a device region at a first main surface of a semiconductor wafer including the first main surface and a second main surface opposite to the first main surface;
burying a first insulator in the first trench;
forming a second trench having a narrower width than the first trench by selectively etching the first insulator and a portion of the semiconductor wafer below the first insulator, and forming a thick film insulation portion made of the first insulator remaining on a side wall of the second trench;
forming a thin film insulation portion, which is thinner than the thick film insulation portion, on an inner wall of the second trench in the portion of the semiconductor wafer so that an isolation insulation film in which the thick film insulation portion and the thin film insulation portion are integrated is formed; and
forming an isolation conductor by burying a conductive material in the second trench.

15. The method of claim 14, wherein the semiconductor wafer includes:
a first impurity region of a first conductivity type formed at the second main surface;
a second impurity region of a second conductivity type formed at the first main surface; and
a buried region of the second conductivity type buried between the first impurity region and the second impurity region,
wherein the first trench is formed from the first main surface through the second impurity region and the buried region so that a bottom of the first trench reaches the first impurity region.

16. The method of claim 15, further comprising: forming a sinker region of the second conductivity type, which has a concentration higher than a concentration of the second impurity region, along a side wall of the first trench in the second impurity region, by implanting a second conductivity type impurity into an inner wall of the first trench, before burying the first insulator.
